(19) United States
(12) Patent Application Publication
(10) Pub. No.: US 2012/0133905 A1
(43) Pub. Date: May 31, 2012

(54) Microprojector and manufacturing method for a microprojector

(76) Inventors: Frank FISCHER, Gomaringen (DE); Michael KRUEGER, Reutlingen (DE)

(21) Appl. No.: 13/303,530

(22) Filed: Nov. 23, 2011

(30) Foreign Application Priority Data
Nov. 26, 2010 (DE) 10 2010 062 017.3

(51) Int. Cl. G02B 21/36; H05K 13/00

(52) U.S. Cl. 353/39; 29/592.1

(57) ABSTRACT

A microprojector is described, in which the microprojector includes a light source, at least one optical imaging arrangement for creating an image with the aid of the light source, at least one electrical arrangement for activating the light source, and a damping element for damping mechanical shocks of the microprojector. Also described is a method for manufacturing a microprojector as well as a corresponding utilization.

### RELATED APPLICATION INFORMATION

The present application claims priority to and the benefit of German patent application no. 10 2010 062 017.3, which was filed in Germany on Nov. 26, 2010, the disclosure of which is incorporated herein by reference.

### FIELD OF THE INVENTION

The present invention relates to a microprojector as well as a method for manufacturing a microprojector.

### BACKGROUND INFORMATION

Microprojectors are mainly used in the field of consumer electronics, for example in mobile phones or notebooks. They are used to project images or to show movies if no stationary projector is available but nevertheless a presentation or a lecture is to be given to several people, for example with the aid of slides or diagrams.

Microprojectors generally include a light source, an image optical system, diverse electronic components and carrier components. They are usually situated together in a housing, either within the housing of the notebook or mobile phone or also in a separate housing.

A microprojector has become known from U.S. Pat. No. 6,480,634 B1 which includes a laser source whose laser light is transmitted to an image optical system with the aid of an optical fiber. A light modulator which is controlled with the aid of an electronic arrangement controls, in turn, the image optical system, to project an image. For this purpose, it is necessary to adjust and fixate the image optical system, e.g., in the form of microlenses, etc., and the light sources in their position in relation to one another. However, when used in a mobile manner, shocks often act on the microprojector from the outside.

### SUMMARY OF THE INVENTION

In the exemplary embodiments and/or exemplary methods of the present invention, a microprojector is defined which includes a light source, at least one optical imaging arrangement for creating an image with the aid of the light source, at least one electrical arrangement for activating the light source, and a damping element for damping of mechanical shocks of the microprojector.

In the exemplary embodiments and/or exemplary methods of the present invention, a method is defined for manufacturing a microprojector, in particular according to at least one of the further descriptions herein, which includes the steps placing a light source onto a carrier, placing an optical imaging arrangement onto the carrier, placing an electrical arrangement onto the carrier, and placing a damping element for damping mechanical shocks of the microprojector.

In the exemplary embodiments and/or exemplary methods of the present invention, a utilization of a microprojector according to at least one of the further descriptions herein in a mobile unit is defined, in particular a mobile phone or a notebook for creating an image.

In the description and in particular in the claims, microprojectors may be understood to be picoprojectors.

The advantage achieved with the exemplary embodiments and/or exemplary methods of the present invention is that it significantly expands the flexibility of the microprojector, since the area of application of such a projector may, for example, be applied outdoors or also in transportation under significant vibrations, e.g., in trains, etc. Furthermore, a microprojector of this type is also less sensitive with respect to accidental misuse, e.g., dropping of the mobile phone or the notebook in which the microprojector is applied.

Further features and advantages of the exemplary embodiments and/or exemplary methods of the present invention are described in herein.

According to one advantageous refinement of the exemplary embodiments and/or exemplary methods of the present invention, the damping element is implemented as a mechanical low-pass filter. The advantage thus achieved is that heavy, temporarily occurring vibrations may be damped or compensated for.

According to another advantageous refinement of the exemplary embodiments and/or exemplary methods of the present invention, the light source and the optical imaging arrangement are situated on the damping element. The advantage thus achieved is that both the light generating arrangement and the imaging arrangement, e.g., the light source and the optical imaging arrangement, are situated on the damping element and are thus decoupled from mechanical interferences which act on the microprojector from the outside.

According to another advantageous refinement, the optical imaging arrangement include a light guide. In this way, it is possible to reliably supply the light of the light source to the optical imaging arrangement.

According to another advantageous refinement of the exemplary embodiments and/or exemplary methods of the present invention, the damping element has spring elements and/or soft-elastic materials. The advantage thus achieved is that the damping element may be manufactured simply and cost-effectively.

According to another advantageous refinement of the exemplary embodiments and/or exemplary methods of the present invention, the damping element is implemented in particular as a plastic and/or elastic stop structure. The advantage thus achieved is that the excessive acceleration at the time of impact of the mobile phone or notebook may thus be at least partially absorbed with the aid of the damping element.

According to another advantageous refinement the electrical arrangement include a mechanically flexible terminal. The advantage thus achieved is that the electrical terminals, too, are thus largely rugged against mechanical shocks.

According to another advantageous refinement of the method, the damping element is manufactured with the aid of 2K injection molding, in particular together with the carrier. The advantage thus achieved is that the damping element may be manufactured simply and cost-effectively, in particular together with the carrier.

According to another advantageous refinement of the method, the damping element is inserted into a housing of the microprojector. The advantage thus achieved is that complex mountings or fixings of the damping element in the housing may be dispensed with.

Further advantages and features of the exemplary embodiments and/or exemplary methods of the present invention are derived from the following description of exemplary embodiments with reference to the figures.

### BRIEF DESCRIPTION OF THE DRAWINGS

FIG. 1 schematically shows a microprojector according to a first specific embodiment of the present invention.

FIG. 2 schematically shows a microprojector according to a second specific embodiment of the present invention.

FIG. 3 schematically shows a microprojector according to a third specific embodiment of the present invention.

FIG. 4 schematically shows a microprojector according to a fourth specific embodiment of the present invention.

FIG. 5 schematically shows a microprojector according to a fifth specific embodiment of the present invention.

FIG. 6 shows steps of a method for manufacturing a microprojector according to a first specific embodiment of the present invention.

### DETAILED DESCRIPTION

In the figures, the same reference numerals identify elements that are identical or have an identical function, unless described otherwise.

FIG. 1 schematically shows a microprojector P according to a first specific embodiment of the present invention. In FIG. 1, reference numeral 1 identifies a micromirror which is situated on a damping element 9, 52 which is embedded in an electrical carrier 4. Furthermore, electrical components 3, e.g., driver, passive components, video decoder, etc., are situated on electrical carrier 4. Furthermore, an electrical terminal 5 is situated on electrical carrier 4 for making electrical energy available to the microprojector. Furthermore, a light source 2 in the form of a laser 2, and optical components in the form of lenses as well as mirrors (8), are situated on carrier 4. Laser 2 emits a light beam 6 essentially parallel to the extension of electrical carrier 4. Light beam 6 traverses optical components 8, and strikes micromirror 1 which deflects beam 6 for projecting an image in an output beam 7 which projects an image, for example on a wall. Damping element 9, 52 includes spring elements 52 which decouple a part of electrical carrier 4 from the rest of electrical carrier 4 for damping purposes. The low-pass filter effect of damping element 9, 52 damps or absorbs shock vibrations, which occur in the housing of microprojector P, for example upon an impact of a mobile phone, which is provided with microprojector P, on a floor, and/or transmits them with lower frequencies or smaller amplitudes to micromirror 1, which is situated on damping element 9, 52.

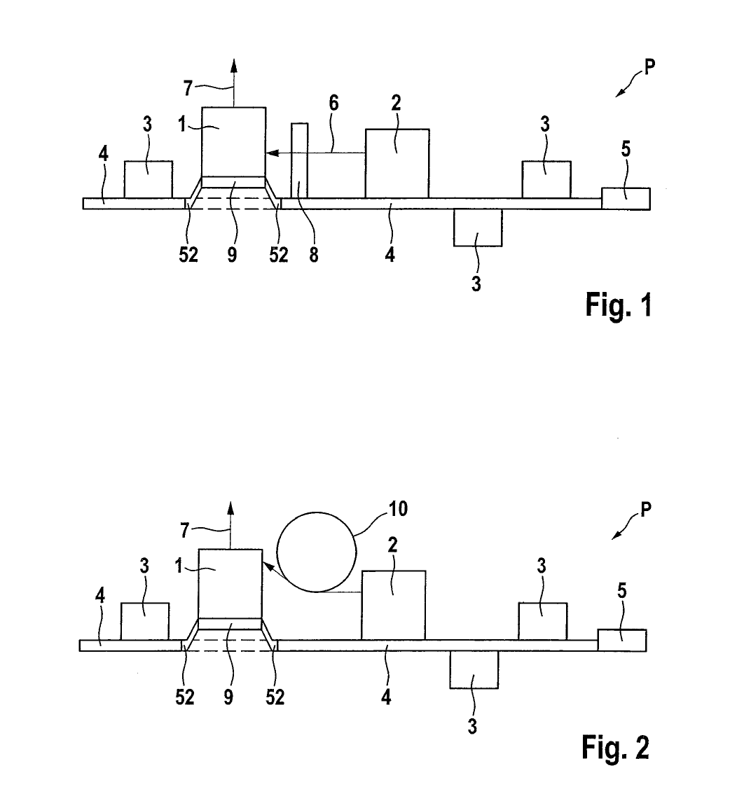

FIG. 2 schematically shows a microprojector according to a second specific embodiment of the present invention. FIG. 2 shows an essentially similar design of microprojector P according to FIG. 1. In contrast to FIG. 1, a light guide structure 10, e.g., a flexible glass fiber, is situated between laser 2 and micromirror 1. Here, it is advantageous that no free space optics is necessary which depends on a stable positional relationship between light source 2 and micromirror 1. This allows for a positional decoupling between micromirror 1 and the light source in the form of a laser 2.

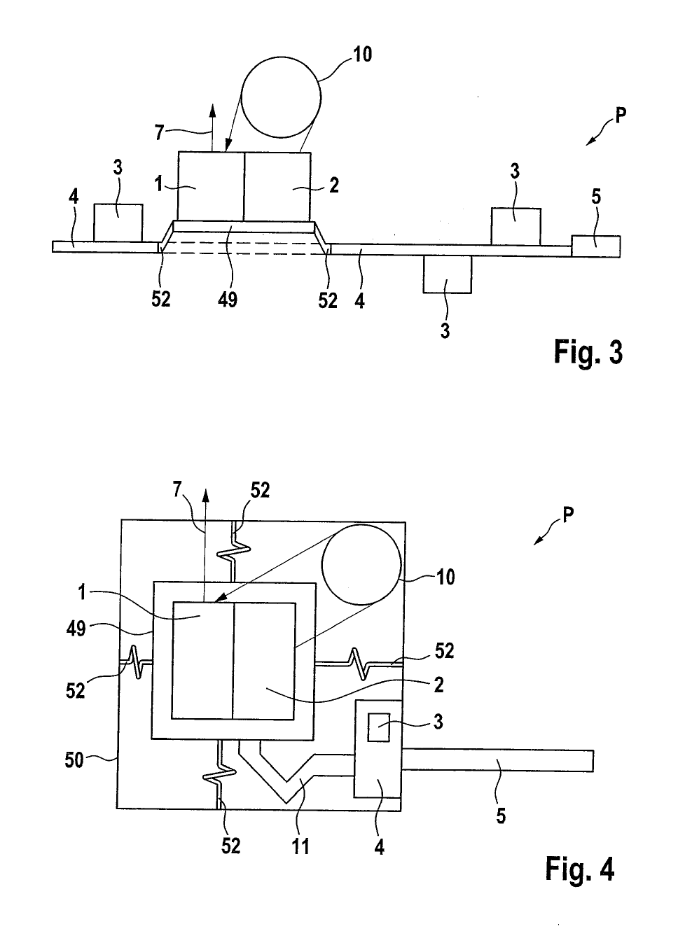

FIG. 3 schematically shows a microprojector according to a third specific embodiment of the present invention. In FIG. 3, a microprojector P according to FIG. 2 is essentially shown. In contrast to FIG. 2, laser 2 and micromirror 1 are situated on a shared electrical carrier 49 which is decoupled from electrical carrier 4 and the housing via damping elements 52. On shared electrical carrier 49, the components which are to be optically adjusted in relation to one another, in particular also optical components 8 (not shown in FIG. 3), are thus situated. For the manufacturing, it is recommended that all components which require an optical adjustment in relation to one another be situated together on carrier 49, since they then may be manufactured in one sequence. If a flexible light guide 10 is used for optically connecting laser 2 and micromirror 1 (as shown in FIG. 3), placing laser source 2 and micromirror 1 on shared carrier 49 becomes more flexible.

FIG. 4 schematically shows a microprojector according to a fourth specific embodiment of the present invention. FIG. 4 shows a schematic top view on a microprojector P in the form of a module having housing 50. Housing 50 is essentially built in the form of a square. In the center of housing 50, shared electrical carrier 49 is situated, on which, in turn, micromirror 1 and laser 2 are located. Laser 2 is, in turn, connected to micromirror 1 via an optical light guide 10. In this case, shared electrical carrier 49 is connected to housing 50 for damping purposes with the aid of four damping elements 52, each of which is essentially situated parallel to a side of square housing 50. Furthermore, electrically flexible connecting elements 11 are situated in order to connect laser 2 to electrical components 3 or electrical connecting elements 4 [sic; 11]. Furthermore, electrical connecting elements 4 [sic; 11] have a plug connector 5 for connecting an external power source, etc.

Due to the spring-mass system of shared electrical carrier 49 and damping elements 52 in the form of springs, a mechanical low-pass filter is created which damps shock vibrations on housing 50 and forwards these, in a filtered state, to shared electrical carrier 49 and micromirror 1 and laser 2 located thereon. In this case, laser 2 as well as micromirror 1 may be situated on shared electrical carrier 49 having soft-elastic materials. Here, it is particularly advantageous if optical light guide 10 is situated directly on micromirror 1 and is situated in rigid mechanical linkage to micromirror 1, so that a flexible connection between shared electrical carrier 49 and micromirror 1 does not negatively affect the adjustment of optical light guide 10.

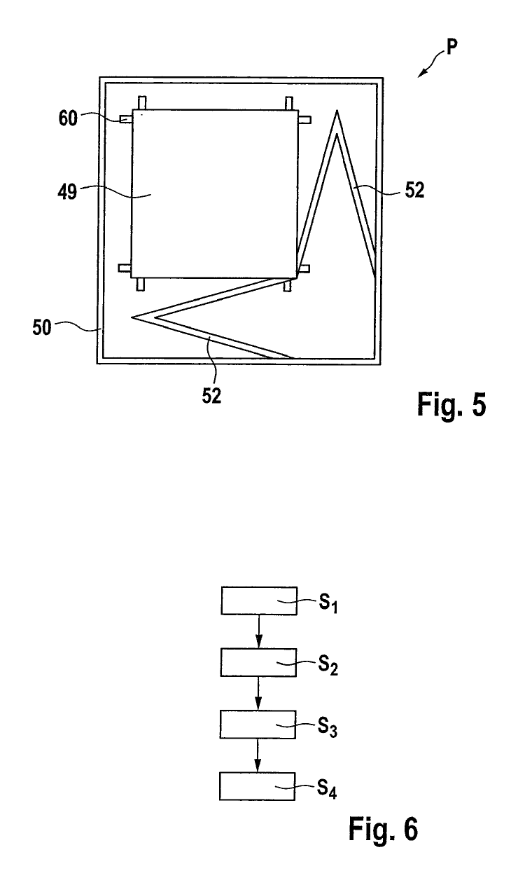

FIG. 5 schematically shows a microprojector according to a fifth specific embodiment of the present invention. In contrast to FIG. 4, in FIG. 5, shared electrical carrier 49 is situated with housing 50 using only two springs 52 instead of four springs 52 according to FIG. 4. Thus, in the case of a vibration of housing 50, not all vibration amplitudes are transmitted to shared electrical carrier 49. Shared electrical carrier 49 has two projecting overload stops 60 at each of its corners. In this case, it is possible to provide only one overload stop 60 or more than two projecting overload stops 60, for example three overload stops 60. In this case, both springs 52 are connected to two adjacent sides of housing 50 and are situated on shared electrical carrier 49 at a shared corner, although on different sides of shared electrical carrier 49. In this case, shared electrical carrier 49 and springs 52 are implemented in such a way that only frequencies are transmitted which essentially lie below the resonance frequencies of the optical and/or electrical components which are situated on shared electrical carrier 49. Overload stops 60 are used to damp a collision of shared electrical carrier 49 with housing 50. Soft-elastic materials, such as silicone, may also be used for this purpose. These overload stops 60 may be situated either on shared electrical carrier 49 and/or corresponding to housing 50.

FIG. 6 shows a method for manufacturing a microprojector, in particular according to at least one of Claims 1 through 7. The method includes a first step S₁: placing a light source on a carrier; a second step S₂: placing an optical imaging arrangement on the carrier; a third step S₃: placing an electrical arrangement on the carrier; and a fourth step S₄: placing a damping element for damping mechanical shocks of the microprojector.

Although the present invention has been described above on the basis of exemplary embodiments, it is not limited thereto, but may be modified in multiple ways. For example, it is thus possible to adjust the mechanical behavior of shared electrical carrier 49 and/or springs 52 with the aid of the geometry of the springs, the mass of the oscillating system and the materials used. For this purpose, soft-elastic materials may be used, for example housing 50 may be manufactured from a 2K plastic injection-molded part, silicone being the soft-elastic component.

What is claimed is:

1. A microprojector, comprising:
a light source;
at least one optical imaging arrangement for creating an image with the aid of the light source;
at least one electrical arrangement for activating the light source; and
a damping element for damping mechanical shocks of the microprojector.

2. The microprojector of claim 1, wherein the damping element includes a mechanical low-pass filter.

3. The microprojector of claim 1, wherein the light source and the optical imaging arrangement are situated on the damping element.

4. The microprojector of claim 1, wherein the optical imaging arrangement includes a light guide.

5. The microprojector of claim 1, wherein the damping element includes at least one of a spring element and a soft-elastic material.

6. The microprojector of claim 1, wherein the damping element has at least one of a plastic and an elastic stop structure.

7. The microprojector of claim 1, wherein the electrical arrangement includes a mechanically flexible terminal.

8. A method for manufacturing a microprojector, in particular as recited in at least one of claims 1 through 7, the method comprising:
placing a light source onto a carrier;
placing an optical imaging arrangement onto the carrier;
placing an electrical arrangement onto the carrier; and
placing a damping element for damping mechanical shocks of the microprojector;
wherein the microprojector includes the light source, the at least one optical imaging arrangement for creating an image with the aid of the light source, the at least one electrical arrangement for activating the light source, and the damping element for the damping mechanical shocks of the microprojector.

9. The method of claim 8, wherein the damping element is manufactured with the aid of 2K injection molding, together with the carrier.

10. The method of claim 8, wherein the damping element is inserted into a housing of the microprojector.

11. A microprojector, comprising:
a light source;
at least one optical imaging arrangement for creating an image with the aid of the light source;
at least one electrical arrangement for activating the light source; and
a damping element for damping mechanical shocks of the microprojector;
wherein the microprojector is used with a mobile phone or a notebook, for creating an image.
